(19) United States
(12) Patent Application Publication
(10) Pub. No.: US 2026/0304917 A1
(43) Pub. Date: Oct. 1, 2026

(54) DEVICE WITH FET GATE AND SCHOTTKY BARRIER DIODE IN SAME TRENCH

(71) Applicant: Microchip Technology Incorporated, Chandler, AZ (US)

(72) Inventor: Shesh Mani Pandey, Gilbert, AZ (US)

(73) Assignee: Microchip Technology Incorporated, Chandler, AZ (US)

(21) Appl. No.: 19/571,276

(22) Filed: Mar. 18, 2026

Related U.S. Application Data
(60) Provisional application No. 63/778,654, filed on Mar. 27, 2025.

(51) Int. Cl. H10D 84/00; H10D 62/832; H10D 84/01

(52) U.S. Cl. CPC H10D 84/146; H10D 62/8325; H10D 84/0109

(57) ABSTRACT

A device including both a field-effect transistor gate and a Schottky barrier diode located in a same trench in a volume of semiconductor material, and a method of making the same. A volume of semiconductor material includes a trench. The field-effect transistor includes a gate oxide located within the trench, and a gate material surrounded by the gate oxide within the primary trench. The Schottky barrier diode is located within the trench and is in physical contact with the volume of semiconductor material. The Schottky barrier diode may also be in contact with the gate oxide.

### RELATED APPLICATION

The present U.S. non-provisional patent application is related to and claims priority benefit of an earlier-filed U.S. provisional patent application titled "EMBEDDED SBD TRENCH MOSFET AND METHODS TO MAKE," Serial No. 63/778,654, filed Mar. 27, 2025. The entire content of the identified earlier-filed application is incorporated by reference as if fully set forth herein.

### TECHNICAL FIELD

The present disclosure relates to field-effect transistors and methods of making them, and, more particularly, the various examples described herein concern a device including both a field-effect transistor gate and a Schottky barrier diode located in a same trench in a volume of semiconductor material, and a method of making a device including both a field-effect transistor gate and a Schottky barrier diode located in a same trench in a volume of semiconductor material.

### BACKGROUND

A metal-oxide semiconductor field-effect transistor (MOSFET) is an active, voltage-controlled semiconductor device, in which varying an electrical voltage between a gate and a body controls an electrical current flowing through a semiconductor channel between a drain and a source. Applications for MOSFETs include amplifiers, switches, resistors, regulators, oscillators, and choppers. It is generally desirable to improve the performance and reduce the cost of MOSFETs, but it can be difficult to do so.

This background discussion is intended to provide related information, and is not necessarily prior art.

### SUMMARY

Examples provide a device including both a field-effect transistor (FET) gate and a Schottky barrier diode (SBD) located in a same trench in a volume of semiconductor material, and a method of making a device including both a FET gate and an SBD located in a same trench in a volume of semiconductor material. Broadly, examples physically and functionally integrate a trench FET (e.g., a trench MOSFET) and a trench SBD into a single, compact structure. Examples advantageously improve reverse conduction and lower cost, and a larger diode resulting from the trench structure is advantageously able to handle higher electrical current. In all examples, the Schottky material is at least in part in physical contact with the volume of semiconductor material.

In an example, a semiconductor device comprises a volume of semiconductor material, an integrated metal-oxide semiconductor field-effect transistor (MOSFET), and an integrated Schottky barrier diode (SBD). The volume of semiconductor material may present oppositely spaced apart first and second ends. A trench may extend from the first end of the volume of semiconductor material. The MOSFET may include a source located adjacent the first end of the volume of semiconductor material, a drain spaced from the source such that a channel extends through the volume of semiconductor material between the source and the drain, a gate-oxide within the trench, and a gate material at least in part surrounded by the gate oxide within the trench. The SBD may be located at least in part within the trench and may contact the volume of semiconductor material.

Another example involves a method of making a semiconductor device, according to the following operations. A volume of semiconductor material may be provided to include a first end and a second end. A primary trench may be formed extending from the first end of the volume of semiconductor material toward the second end. Formation of a FET may include the following operations. A source may be implanted at the first end of the volume of semiconductor material, and a drain may be provided spaced apart from the source. A gate oxide may be deposited into the primary trench in the semiconductor material, a first trench may be formed in the gate oxide within the primary trench, and a doped gate material may be deposited in the first trench such that the doped gate material is at least in part surrounded by the gate oxide. The SBD may be made according to the following operations. A second (or SBD) trench may be formed in the gate oxide within the primary trench, wherein the second trench is spaced apart from the first trench and abuts the volume of semiconductor material, and a Schottky material may be deposited in the second trench such that Schottky material is at least in part in physical contact with the volume of semiconductor material.

The preceding examples may further include any one or more of the following features.

The drain may be located at the second end of the volume of semiconductor material.

The SBD may contact the gate oxide within the trench.

The SBD may include a Schottky metal and an SBD contact, each of which includes at least a portion thereof located within the trench.

The Schottky metal and the SDB contact may be integrally formed.

The Schottky metal may be interposed between the SBD contact and the gate oxide and between the SBD contact and the volume of semiconductor material.

The SBD contact may be interposed between the Schottky metal and the gate oxide.

The trench may have a trench bottom surface spaced from the first end of the volume of semiconductor material. The Schottky metal may extend continuously between the trench bottom surface and the first end of the volume of semiconductor material.

The SBD contact may be spaced from the trench bottom surface.

The volume of semiconductor material may present opposite laterally spaced first and second sides. The trench may have a trench bottom surface and opposite first and second laterally spaced trench side surfaces, each of which extends between the first end of the volume of semiconductor material and the trench bottom surface.

The gate oxide may line the first trench side surface and at least a portion of the trench bottom surface. The source may be located between the first side of the volume of semiconductor material and the first trench side surface. The SBD may be located adjacent the second trench side surface.

The MOSFET may include a first doped well contacting the source and the gate oxide to define a portion of the channel extending between the source and drain. The MOSFET may include a second doped well located below the trench bottom surface.

The second doped well and the first trench side surface may be equally spaced from the first side of the volume of semiconductor material. The second doped well may be spaced closer to the second side of the volume of semiconductor material than the second trench side surface.

The first doped well may include a channel-defining first well portion at the first trench side surface, with the channel-defining first well portion being spaced from the trench bottom surface so as to expose the gate-oxide along a portion of the first trench side surface. The first doped well may include a second portion spaced from the first trench side surface. The second portion may project further toward the second end of the volume of semiconductor material than the trench bottom surface and cooperate with the second doped well to define a JFET region therebetween.

The SBD may contact the second doped well.

The MOSFET may include a well contacting the source and the gate oxide, which is the only source-well-oxide interface of the MOSFET so as to define a single channel extending between the source and drain.

The trench may have opposite first and second spaced apart trench side surfaces, each of which extends from the first end of the volume of semiconductor material. The SBD may be located along at least a portion of the second trench side surface. The gate oxide may include a first side oxide portion lining the first trench side surface and a second side oxide portion located between the gate and the SBD. The second side oxide portion may be thicker, in a dimension measured between the first and second trench side surfaces, than the first side oxide portion.

The SBD may include a Schottky metal that has at least a portion thereof lining the second trench side surface. The SBD may include an SBD contact located between the second side oxide portion and the at least a portion of the Schottky metal.

The trench may have a trench bottom surface and opposite first and second laterally spaced trench side surfaces, each of which extends between the first end of the volume of semiconductor material and the trench bottom surface. The MOSFET may include a first doped well contacting the source and the gate oxide to define a portion of the channel extending between the source and drain. The MOSFET may include a second doped well located below the trench bottom surface. The SBD may contact the second doped well.

The device may include an electrical connection electrically connecting the MOSFET and the SBD.

The Schottky material may also be at least in part in physical contact with the gate oxide within the primary trench.

The Schottky material may include aluminum, titanium, molybdenum, platinum, chromium, and tungsten and combinations thereof.

Making the FET may further include implanting a first doped well located at least in part below the source, and implanting a second doped well located at least in part below the primary trench.

The method may further include providing an electrical connection electrically connecting at least the source and the SBD.

This summary is not intended to identify essential features of the examples and is not intended to be used to limit the scope of the claims. These and other aspects of the present disclosure are described below in greater detail.

### BRIEF DESCRIPTION OF THE DRAWINGS

Examples are described in detail below with reference to the attached drawing figures, wherein:

FIG. 1 is a cross-sectional elevation view of a first example of a device that includes both a FET (e.g., a MOSFET) and an SBD, wherein both a gate component of the FET and the SBD are located in a same trench in a volume of semiconductor material and a Schottky contact extends into a Schottky material;

FIG. 2 is a cross-sectional elevation view of a second example of the device, wherein both the gate component of the FET and the SBD are located in the same trench in the semiconductor material and the Schottky contact is located above the Schottky material;

FIG. 3 is a cross-sectional elevation view of a third example of the device, wherein both the gate component of the FET and the SBD are located in the same trench in the semiconductor material and the Schottky contact extends along a side of the Schottky material;

FIG. 4 is a flowchart of operations in an example of a method of making a device that includes both a FET and an SBD, wherein both a gate component of the FET and the SBD are located in a same trench in a volume of semiconductor material;

FIG. 5A is a cross-sectional elevation view of the result of an operation in the method of FIG. 4, wherein various doped regions are formed in the volume of semiconductor material to make the FET;

FIG. 5B is a cross-sectional elevation view of the result of an operation in the method of FIG. 4, wherein a primary trench is created in the volume of semiconductor material adjacent to a source component of the FET;

FIG. 5C is a cross-sectional elevation view of the result of an operation in the method of FIG. 4, wherein a gate oxide is provided in the primary trench;

FIG. 5D is a cross-sectional elevation view of the result of an operation in the method of FIG. 4, wherein a gate trench is formed in the gate oxide on one side of the primary trench, adjacent to the source component, in the volume of semiconductor material;

FIG. 5E is a cross-sectional elevation view of the result of an operation in the method of FIG. 4, wherein a doped gate material is provided in the gate trench;

FIG. 5F is a cross-sectional elevation view of the result of an operation in the method of FIG. 4, wherein an SBD trench is formed in the gate oxide on another side of the primary trench, opposite the source component, in the volume of semiconductor material;

FIG. 5G is a cross-sectional elevation view of the result of an operation in the method of FIG. 4, wherein a Schottky material of the SBD is provided in the SBD trench, wherein the Schottky material is at least in part in physical contact with the volume of semiconductor material; and

FIG. 5H is a cross-sectional elevation view of the result of an operation in the method of FIG. 4, wherein an SBD contact is provided at least in part in physical contact with the Schottky material.

The figures are not intended to limit the examples to the specific details depict. The drawings are not necessarily to scale.

### DETAILED DESCRIPTION

In the following detailed description, reference is made to the accompanying drawings, which form a part hereof and in which are shown, by way of illustration, specific examples in which the present disclosure may be practiced. These examples are described in sufficient detail to enable a person of ordinary skill in the art to practice the present disclosure. However, other examples may be utilized, and structural, material, procedural, operational, and other changes may be made without departing from the scope of the disclosure. Unless clearly understood or expressly identified otherwise, structures, materials, procedures, operations, and other aspects described in the context of one example may be incorporated into other examples. The illustrations presented herein are not meant to be actual views of any particular method, system, device, or structure, but are merely idealized representations that are employed to describe the examples of the present disclosure. Similar structures or components in the various drawings may retain the same or similar numbering for the convenience of the reader; however, any similarity in numbering does not necessarily mean that the structures or components are necessarily identical in size, composition, configuration, or any other property. Terms of relative location and direction (e.g., above, below, left, right, upper, lower) may be used to facilitate the present descriptions of examples with reference to the figures, but unless clearly understood or expressly identified otherwise, these terms are not meant to be limiting with regard to location, direction, or overall orientation, and may, for example, change as a result of a change in overall orientation. It will be readily understood that the components of the examples as generally described herein and illustrated in the drawings could be arranged and designed in a wide variety of different configurations. Thus, the following description of various examples is not intended to limit the scope of the present disclosure but is merely representative of various examples.

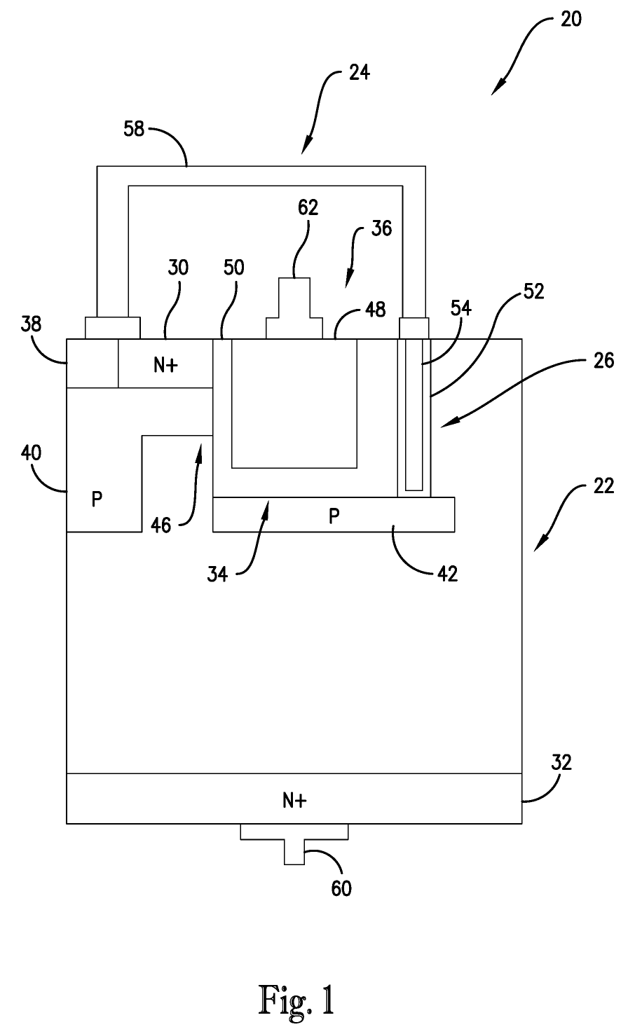

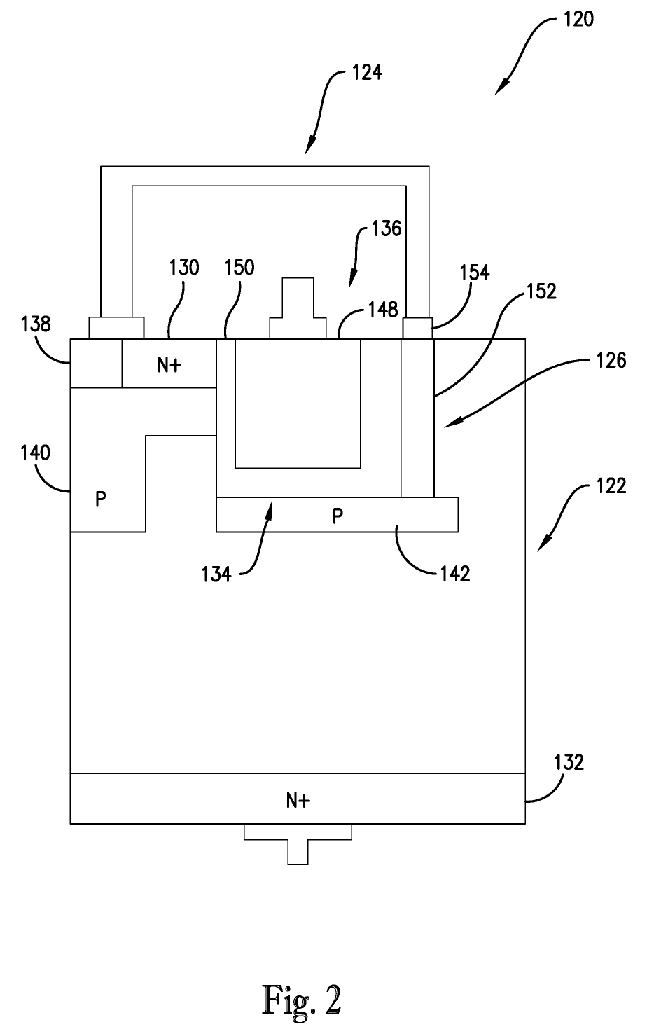

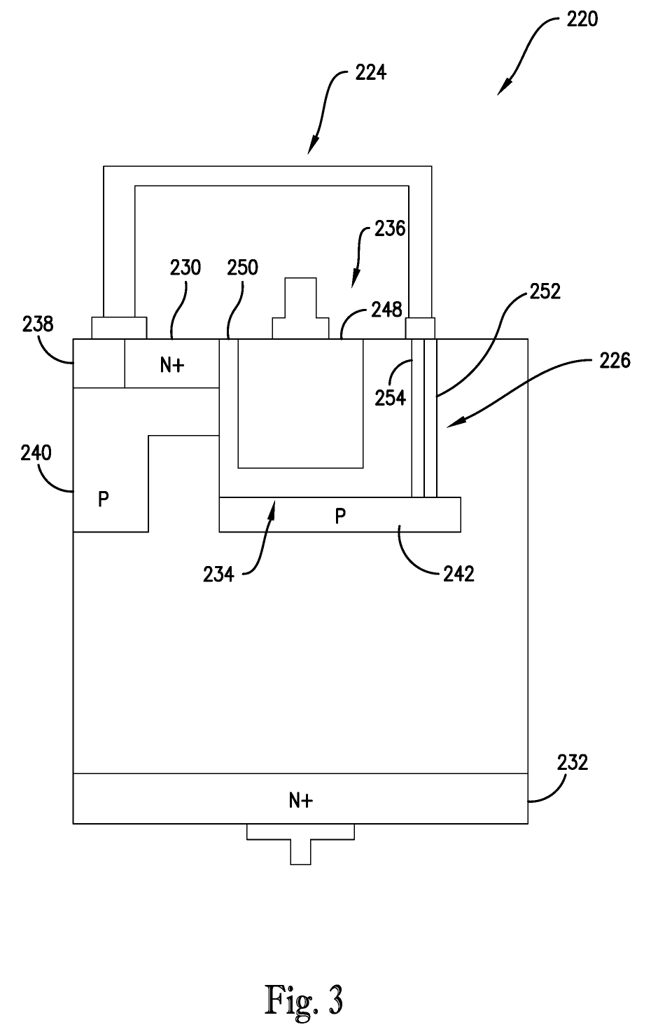

Examples concern a device including both a FET (e.g., a MOSFET) gate and an SBD located in a same trench in a volume of semiconductor material, and a method of making such a device. Broadly, examples physically and functionally integrate a trench FET and a trench SBD into a single, compact structure. In various examples, a Schottky contact may extend into a Schottky material (as seen in FIG. 1), the Schottky contact may be located above the Schottky material (FIG. 2), and the Schottky contact may extend along a side of the Schottky material (FIG. 3). In all examples, the Schottky material is at least in part in physical contact with the volume of semiconductor material.

Examples are advantageously suitable for both low-voltage and high-voltage applications, including voltages exceeding one thousand volts (1,000 V). Specific examples may be suitable for voltages of approximately twelve hundred volts (1,200 V). Examples advantageously improve reverse conduction and lower cost, and the larger diode resulting from the trench structure is advantageously able to handle higher electrical current. In particular, the improved reverse conduction (i.e., the third quadrant performance) of a silicon carbide (SiC) MOSFET is desirable for next-generation compact power electronics. Integration of the SBD with the SiC MOSFET provides an efficient mechanism for avoiding bipolar degradation when the parasitic P-N body diode is opened. For example, if the forward voltage of the body diode of the MOSFET is three-and-one-half volts (3.5 V), and the forward voltage of the SBD is one-and-on-half volts (1.5 V), then the forward voltage drop is reduced by two volts (2 V), resulting in lower forward voltage losses. Further, integrating the SBD rather than connecting a discrete SBD provides the advantages of using less space, lowering cost, and requiring fewer dies in the manufacturing process. Additionally, the integrated SBD may improve a switching time of the device by activating quicker than the FET. Additionally, the integrated SBD may improve fault tolerance by conducting electrical energy in the event of a failure of one or more components of the FET.

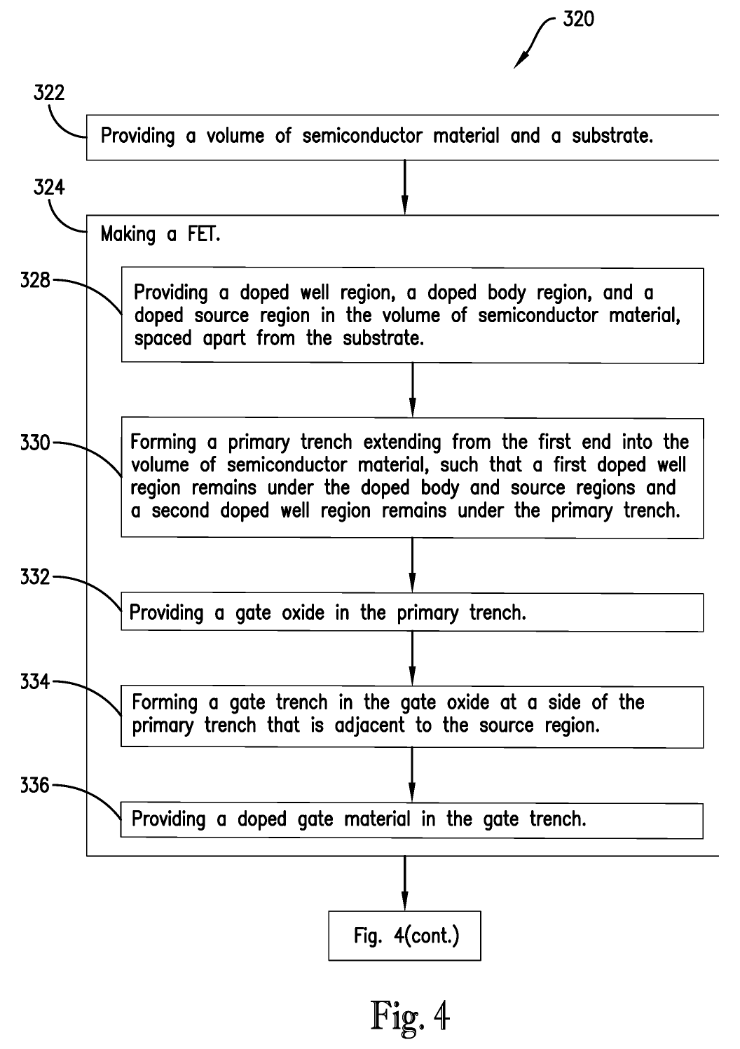

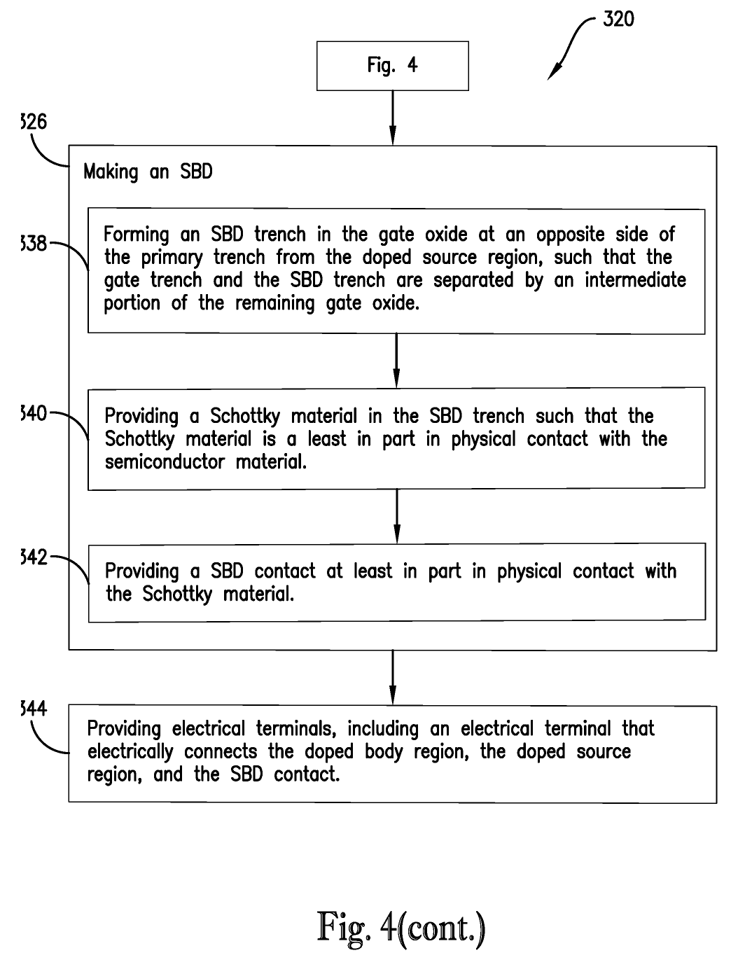

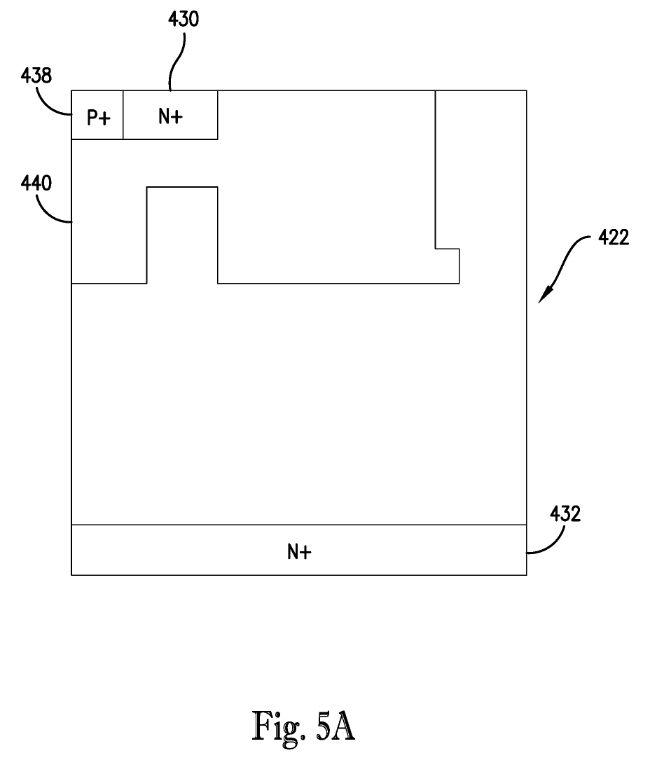

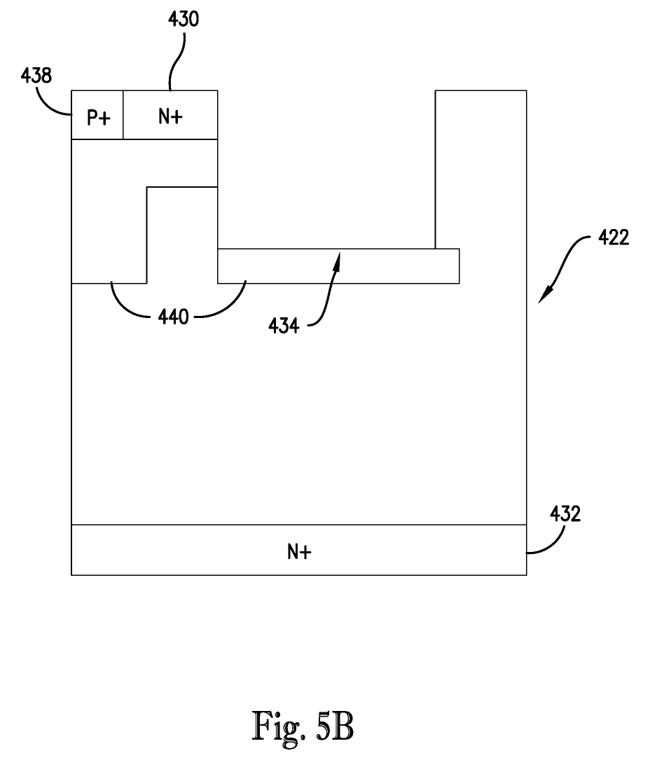

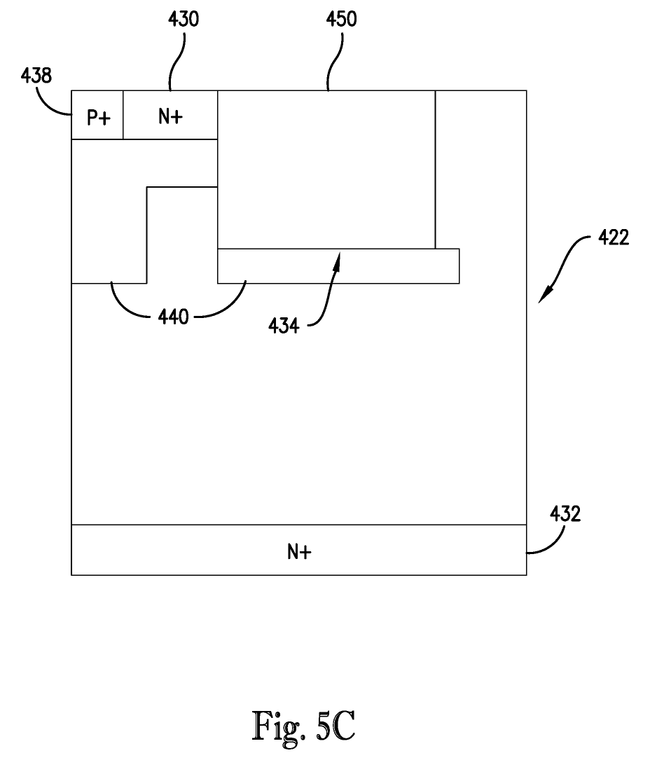

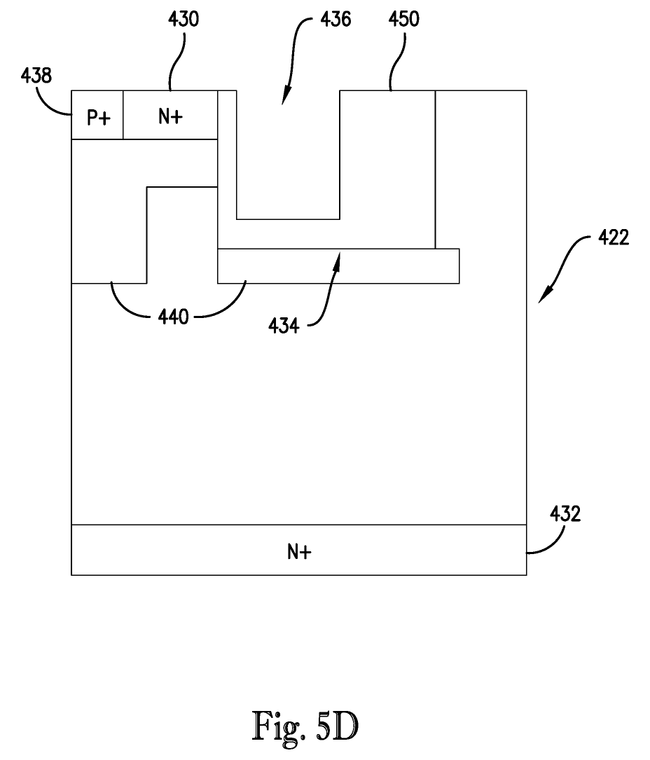

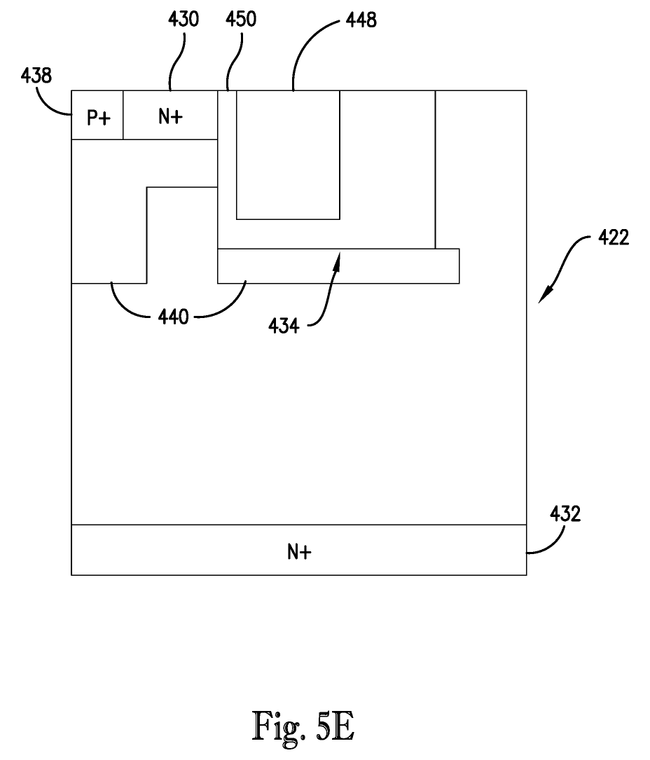

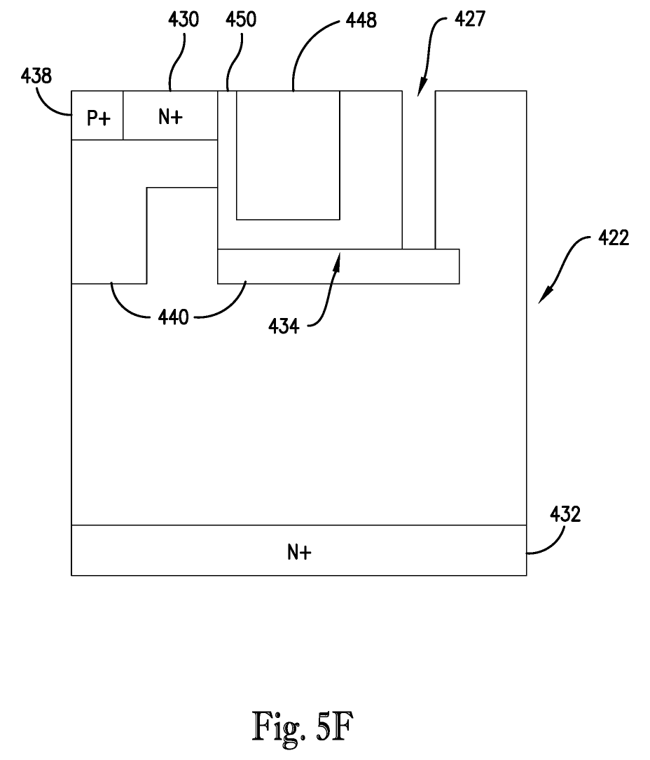

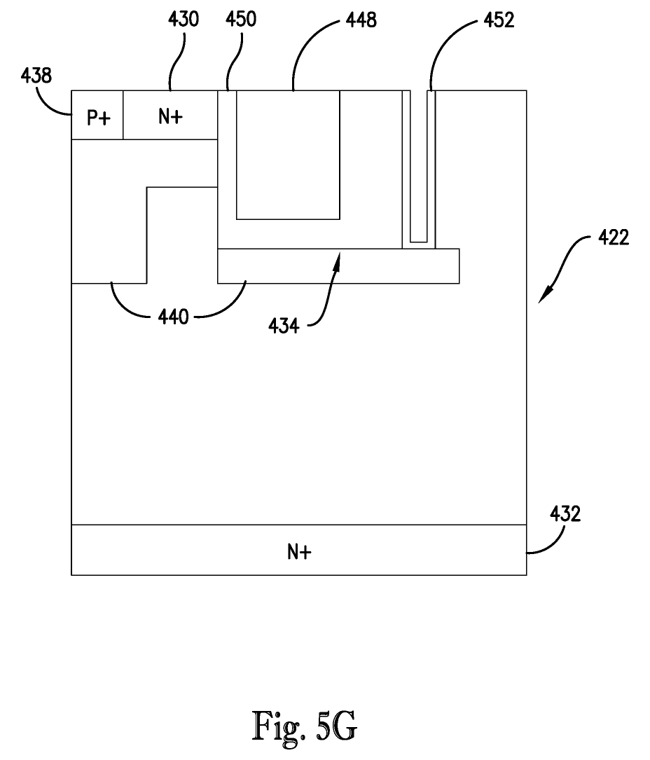

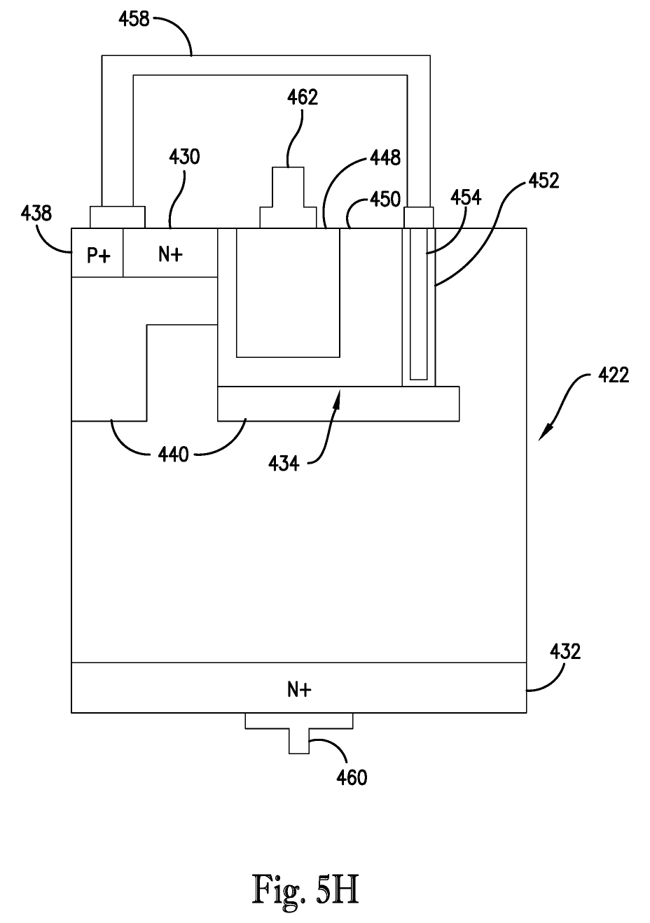

Broadly, an electronic semiconductor device, examples of which are seen in FIGS. 1-3, and a method of making such a device, examples of which are seen in FIGS. 4-5H, include a FET gate, including a doped gate material at least in part surrounded by a gate oxide, and an SBD, including a Schottky material and a Schottky contact, located in the same trench in a volume of semiconductor material. As desired, there may be additional trenches in the volume of semiconductor material for other structures or purposes, but the FET gate and the SBD are located in the same trench. In one implementation of the method, this primary trench may be filled with a gate oxide, and a first or gate trench may be formed in the gate oxide to receive the doped gate material and a second or SBD trench may be formed in the gate oxide to receive the Schottky material. The gate trench and the SBD trench in the gate oxide are within the same trench (the primary trench) in the semiconductor material.

In more detail, referring to FIG. 1, a first example of a device 20 is shown including a volume of semiconductor material 22, an integrated trench FET 24, and an integrated trench SBD 26. The volume of semiconductor material 22 may include opposite and vertically spaced apart first and second ends and opposite and laterally spaced apart left and right sides. In an N-type device, the volume of semiconductor material 22 may include an N-type epitaxial semiconductor material. The integrated FET 24, which in this example may be a MOSFET, may include a source 30, a drain 32, a primary trench 34, a gate 36, a first doped body contact 38, a first doped well 40, and a second doped well 42. The various structures and materials of the FET 24 may be implanted (using, e.g., an ion implanter), deposited, or otherwise provided using a suitable technique in or on respective sub-volumes of the volume semiconductor material 22. In various examples, the structures, materials, and their respective sizes, dimensions, thicknesses, widths, lengths, and positions may vary depending on the particular application.

In the illustrated example, the volume of semiconductor material 22 is formed of silicon carbide (SiC). However, according to certain examples, the volume of semiconductor material may alternatively be formed of silicon, gallium nitride (GaN), or other suitable materials or material combinations.

The source 30 may be located adjacent or at the first end of the volume of semiconductor material 22, between the left side of the volume of semiconductor material 22 and the trench 34, and abutting a left side surface of the trench 34. The source 30 may provide an entrance for charge carriers (which are, in the case of an N-type device, electrons). In an N-type device, the source 30 may be constructed from or include N+ dopants implanted into the volume of semiconductor material 22. During operation, a channel 46 through which the charge carriers flow may form below the source 30.

The drain 32 may be located spaced apart from the source 30. For example, the drain 32 may be located opposite the source 30 at the second end of the volume of semiconductor material 22. According to certain alternative examples, the drain may be positioned elsewhere relative to (e.g., on) the volume of semiconductor material, such as the same (first) end of the volume of semiconductor material. In an N-type device, the drain 32 may be constructed from or include an N+ substrate on which the volume of semiconductor material 22 may be grown or otherwise provided. The drain 32 may provide an exit for the charge carriers that flow from the source 30.

The primary trench 34 may be located adjacent to the source 30 and may extend from the first end of the volume of semiconductor material 22 toward the second end. The primary trench 34 may be formed by an etching process or other suitable technique. The dimensions of the trench 34 may vary, but, as discussed below, the dimensions may be sufficient to accommodate both a gate trench and an SBD trench (as described below) in the trench 34. The trench may present a trench bottom surface spaced between the first and second ends of the volume of semiconductor material 22, a left trench side surface spaced from the left side of the volume of semiconductor material 22, and a right trench side surface spaced from the right side of the volume of semiconductor material. The illustrated trench side surfaces are depicted as extending vertically between the trench bottom surface and the first end of the volume of semiconductor material. However, according to certain examples, the trench side surfaces may extend at an angle or include an offset(s) between the trench bottom surface and the first end of the volume of semiconductor material. Further, alternative spacing and/or locations of the trench or bottom and side surfaces are within the ambit of certain examples of the device.

The gate 36 may be located within the primary trench 34 and may include a doped gate material 48 and a gate oxide 50. According to certain examples, portions of the gate 36 may alternatively be located outside the trench 34. The gate 36 may facilitate controlling the flow of charge carriers through the channel 46. The doped gate material 48 may be constructed from or include a doped polysilicon material. The doped gate material 48 may be at least partially surrounded (as shown in the figures, on the left, right, and bottom) by the gate oxide 50. In the illustrated example, the gate oxide 50 may line the left trench side surface and the bottom trench surface. Further, along the right margin of the gate material 48, the gate oxide 50 may extend continuously between the trench bottom surface and the first end of the volume of semiconductor material 22. The gate oxide 50 may consequently surround the entirety of the gate material 48 within the trench 34, excluding the top margin of the gate material 48, which is illustrated as being generally coplanar with the first end of the volume of semiconductor material. The gate material 48 may be offset within the trench 34, such that a right portion of the gate oxide 50 defined between the gate material 48 and the SBD 26 is thicker (in a dimension measured between the left and right trench side surfaces) than a left portion of the gate oxide 50 defined between the gate material 48 and the left trench side surface (source 30). The gate oxide 50 may be constructed from or include a dielectric material, such as silicon dioxide (SiO2). As discussed below, during the making of the device 20, the primary trench 34 may be filled with the gate oxide 50, a gate trench may be etched or otherwise formed in a portion of the gate oxide adjacent to the source 30 (as shown in the figures, on the left side of the primary trench 34), and the doped gate material may be deposited or otherwise provided in the gate trench.

The first doped body contact 38, may be located adjacent to the source 30 and opposite the primary trench 34. In an N-type device, the first doped body contact 38 may be formed from or include P++ dopants implanted into the volume of semiconductor material 22. The first doped well 40 may be generally located below and at least in part in physical contact with the body contact 38, and, as such, may extend from the first side of the volume of semiconductor material 22 to the left side of the primary trench 34. The first doped well 40 may also be located below the source 30 and in contact with the source 30 and gate oxide 50 to define a portion of the channel extending between the source 30 and the drain 32. It is further noted that the first well 40 cooperates with the source 30 and the gate oxide 50 to present the only source-well-oxide interface of the MOSFET 24, thereby defining a single channel between the source 30 and drain 32. It will be appreciated, however, that certain examples contemplate the MOSFET being a dual channel transistor. The upper (or first) portion of the first well 40 in contact with the body contact 38 and source 30 and extending between the left side of the volume of semiconductor material 22 and the left trench side surface (or gate oxide 50) may be referred to as a channel-defining first portion of the first doped well 40. The channel-defining first portion may be spaced from the trench bottom surface so as to expose the gate oxide 50 along a portion of the left trench side surface. The first well 40 may also include a lower (or second) portion extending below and from the channel defining first portion. The second portion of the first well 40 may be spaced from the left trench side surface (and gate oxide 50) and may extend further toward the second end of the volume of semiconductor material 22 than the trench bottom surface. (In other words, the lowermost margin of the second portion of the first well 40 may be located lower in the volume of semiconductor material 22 than the trench bottom surface, although the lowermost margin of the second portion of the first well 40 may alternatively be located in vertical alignment with or higher than the trench bottom surface.) Additional alternative dimensions, shapes, etc. of the first doped well 40 are within the ambit of certain examples of the device. The first doped well 40 may cooperate with one or more other structures to facilitate controlling the flow of charge carriers through the channel 46, as will be further described.

The second doped well 42 may be generally located below and along the bottom of the primary trench 34 and at least in part in physical contact with the gate 36 and, more particularly, the gate oxide 50 located along the bottom trench surface. In the illustrated example, the second well 42 and the left trench side surface are equally spaced from the left side of the volume of semiconductor material 22. Further, the second well 42 may extend rightward beyond the right trench side surface (such that the rightmost margin of the second well 42 is located closer to the right side of the volume of semiconductor material than the right trench side surface). In the illustrated example, the second well 42 underlies and is in physical contact with the SBD 26, although some examples contemplate spacing (and therefore no physical contact) between the second well 42 and the SBD 26. Yet further, the illustrated second well 42 may extend rightward beyond the SBD 26. Alternative dimensions, shapes, etc. of the second doped well 42 are within the ambit of certain examples of the device. The second doped well 42 may provide electrical isolation and shielding for other components of the FET 24. The second doped well 42 may also cooperate with the lower portion of the first doped well 40 to define a JFET next region of the drift region. In various examples, the first doped well 40 and the second doped well 42 may be separate structures or part of a single continuous structure. In an N-type device, the first and second doped wells 42, 44 may be constructed from or include P or P+ dopants implanted into the volume of semiconductor material 22.

Although not shown, a third doped well or region may be provided between the SBD 26 and the right side of the volume of semiconductor material 22. The third doped well may be located adjacent or at the first end of the volume of semiconductor material 22. The third doped region may be in physical contact with the SBD 26 and spaced from the right side of the volume of semiconductor material 22. The third doped region may only extend along part of the vertical extent of the SBD 26, so as to be spaced from the trench bottom surface. The third doped region may be formed of or include P or P+ dopants implanted into the volume of semiconductor material 22.

The SBD 26 may be located at least in part within the primary trench 34. The SBD 26 may contact the gate oxide 50 within the trench 34. The SBD may include a Schottky material 52 and an SBD contact 54, at least a portion of each of which may be located within the trench 34. (In the example depicted in FIG. 1, the Schottky material 52 and the SBD contact 54 are located entirely within the trench.) The SBD 26 may be located along the right trench side surface – opposite the source 30 and spaced from the gate material 48. The SBD 26 may extend continuously alongside and physically contact the gate oxide 50, with the thicker gate oxide portion being between the SBD 26 and the gate material 48. However, according to some examples, the SBD 26 may alternatively be spaced from and/or not be coextensive (in a vertical direction) with the gate oxide 50. In the example depicted in FIG. 1, any portion of the SBD contact 54 located below the first end of the volume of semiconductor material 22 is surrounded by the Schottky material 52. That is to say, the Schottky material 52 presents a bottom portion extending along the bottom trench surface, a left portion physically contacting the gate oxide 50 and extending continuously between the first end of the volume of semiconductor material and the bottom portion, and a right portion extending continuously along the right trench side surface and between the first end of the volume of semiconductor material and the bottom portion. The SBD contact 54 is located above the bottom portion of the Schottky material 52 (and is therefore spaced from the trench bottom surface) and is interposed and extends continuously between the left and right portions of the Schottky material 52. As discussed below, during the making of the device 20, an SBD trench may be etched or otherwise formed in a portion of the gate oxide 50 that is on the opposite side of the primary trench 34 from the gate 36 (as shown in the figures, on the right side of the primary trench 34), and at least the Schottky material 52 may be deposited or otherwise provided in the SBD trench such that the Schottky material 52 is at least in part in physical contact with the semiconductor material. The SBD contact 54 may extend into the Schottky material 52 (as seen in FIG. 1), may be located above the Schottky material 52 (as seen in FIG. 2), or may extend along a side of the Schottky material 52 (as seen in FIG. 3). As noted, an intermediate portion of the gate oxide 50 between the gate trench and the SBD trench may separate the doped gate material 48 from the SBD 26, and may be relatively thicker than the left gate oxide portion separating the doped gate material 48 from the source 30. The Schottky material 52 may be constructed from or include aluminum, titanium, molybdenum, platinum, chromium, and tungsten, and combinations thereof. The SBD contact 54 may be constructed from or include aluminum, copper, nickel, or combinations thereof. In some examples, the Schottky material and the SBD contact may be formed of the same material. In all examples, the Schottky material 52 may at least in part physically contact the semiconductor material at some point, such as along a side (as shown in the figures, the right side) of the primary trench 34.

The device 20 may further include various electrical terminals electrically connecting elements of the FET 24 and the SBD 26 and facilitating applying various voltages, as described below. For example, a first electrical terminal 58 may be provided to electrically connect the source 30, the first doped body contact 38, and the SBD contact 54. A second electrical terminal 60 may be provided on the drain 32, and a third electrical terminal 62 may be provided on the gate 36.

In operation, when a gate-to-source voltage, Vgs, is applied between the source 30 and the gate 36, an electric field is generated and penetrates through the gate oxide 50 to create inversion layers at the semiconductor-dielectric interface. The inversion layers provide the channel 46 through which electrical current can flow when a drain-to-source voltage, Vds, is applied between the source 30 and the drain 32. More specifically, Vgs controls the width of the depletion region at the P-N junction where the charge carriers of the P- and N-type materials diffuse into each other, which depletes the available concentrations of majority charge carriers in each material, and thereby controls the drain current, Id, from the drain 32 to the source 30. As discussed, the integrated SBD 26 avoids bipolar degradation when the parasitic P-N body diode is opened.

As noted, the illustrated example is a single channel configuration. However, the MOSFET may be alternatively constructed into a dual-channel configuration. For example, the MOSFET may alternatively include including left and right sources on either side of the primary trench and left and right gates in the primary trench. In this dual-channel configuration, the SBD may be located in the primary trench between the left and right gates. The sources, body contacts, and first doped wells may be reproduced as substantially similar mirror-image or flipped-image structures on either side of the trench. Alternatively, one or more of these elements may have different sizes, shapes, positions, or constructions on either side of the trench.

Referring to FIG. 2, a second example of the device 120 is shown which may be substantially similar or identical to the first example of FIG. 1, including the volume of semiconductor material 122; the integrated FET 124, including the source 130, the drain 132, the primary trench 134, the gate 136, the doped gate material 148, the gate oxide 150, the first doped body contact 138, the first doped well 140, and the second doped well 142; and the integrated SBD 126, including the Schottky material 152 and the SBD contact 154. As discussed, the second example device 120 may differ at least or at most in that the SBD contact 154 may be located above the Schottky material 52 and outside of the trench 134.

Referring to FIG. 3, a third example of the device 220 is shown which may be substantially similar or identical to the first example of FIG. 1, including the volume of semiconductor material 222; the integrated FET 224, including the source 230, the drain 232, the primary trench 234, the gate 236, the doped gate material 248, the gate oxide 250, the first doped body contact 238, the first doped well 240, and the second doped well 242; and the integrated SBD 226, including the Schottky material 252 and the SBD contact 254. As discussed, the third example device 220 may differ at least or at most in that the SBD contact 254 may extend along a side of the Schottky material 252. More particularly, the SBD contact 254 may be interposed between the gate oxide 250 and the Schottky material 252, such that the SBD contact 254 (not the Schottky material 252) physically contacts the gate oxide 250. The SBD contact 254 may extend continuously between the first end of the volume of semiconductor material 222 and the trench bottom surface, thereby entirely separating the Schottky material 252 from the gate oxide 250. It is further noted that the Schottky material 252 and the SBD contact 254 engage the second doped well 242.

Referring to FIG. 4, an example of a method 320 of manufacturing a device, such as the example devices 20, 120, 220 described above, including a FET gate and an SBD located in the same trench, may include the operations set forth below. Reference is made to the example devices 20, 120, 220 of FIGS. 1, 2, and 3 and to example results of certain operations of the method shown in FIGS. 5A-5H. Although described and shown as making an N-type MOSFET, the method is readily adaptable to making devices of other types and configurations.

Broadly, making the device 20 may include growing or otherwise providing using substantially any suitable technique a volume of semiconductor material 422, which may become the volume of semiconductor material 22, 122, 222, including first and second ends and first and second sides. The volume of semiconductor material 422 is commonly grown on a substrate 432, which may become the drain (32, 132, 232), located at the second end, as shown in 322 and seen in FIG. 5A. As noted, the drain may be positioned elsewhere relative to the volume of semiconductor material 422, such as on the same (first) end as the source. For an N-type device, the volume of semiconductor material 422 may include an N-type semiconductor material, and the substrate 432 may include an N+ material. Making the device 20 may further include making the FET 24, 124, 224 as shown in 324, and making the SBD 26, 126, 226, as shown in 326.

Making the FET 24, 124, 224 may include implanting or otherwise providing using substantially any suitable technique a doped well region 440, which may become a first doped well 40, 140, 240 and a second doped well 42, 142, 242, a doped body region 438 which may become a doped body contact 38, 138, 238, and a doped source region 430, which may become a source 30, 130, 230 in the volume of semiconductor material 422 at or near the first end. The doped well, body, and source regions 440, 438, 430 may be spaced apart from (e.g., opposite) the substrate 432, wherein the substrate 432 may become a drain 32, 132, 232 as shown in 328 and also seen in FIG. 5A. The shapes, sizes, and other details of these regions may vary depending on the application. For an N-type device, the doped well region 440 may include a P+ dopant, the doped body region 438 may include a P++ dopant, and the source region 430 may include an N+ dopant.

A primary trench 434, which may become the primary trench 34, 134, 234, may be etched or otherwise formed using substantially any suitable technique to extend from the first end into the volume of semiconductor material 422, as shown in 330 and seen in FIG. 5B. As discussed, the FET gate 36, 136, 236 and the SBD 26, 126, 226 share the primary trench 34, 134, 234. As shown in FIGS. 5A and 5B, it may be desirable to form a large volume of a doped well region and then etch the primary trench 434 into this volume of doped well region such that, once the primary trench 434 is formed, a first doped well region 440, which may become the first doped well 40, 140, 240, remains under the doped body region 438 and the doped source region 430 and a second doped well region 442, which may become the second doped well 42, 142, 242, remains under the primary trench 434.

A gate oxide (e.g., SiO2) or other dielectric material 450, which may become the gate oxide 50, 150, 250, may be deposited, grown, or otherwise provided using substantially any suitable technique in the primary trench 34, as shown in 332 and seen in FIG. 5B. A FET gate 36, 136, 236 may be made as follows. A gate trench 437 may be etched or otherwise formed in the gate oxide 450 in the primary trench 434, as shown in 334 and seen in FIG. 5D. The gate trench 437 may be formed at a side (as shown in the figures, the left side) of the primary trench 434 that is adjacent to the doped source region 430. The gate trench 437 may be etched so as to leave a layer of the gate oxide 450 at the sides and bottom of the gate trench 437. A doped gate material (e.g., polysilicon) 448, which may become the doped gate material 48, 148, 248, may be deposited or otherwise provided in the gate trench 437, as shown in 336 and seen in FIG. 5E. In an example, the doped gate material 448 is at least in part surrounded and separated from the semiconductor material 422 at the sides and bottom by the gate oxide 450 (and particularly the portion of the gate oxide 450 remaining at the sides and bottom of the gate trench 437 after formation of the gate trench 437).

The SBD 26, 126, 226 may be made as follows. An SBD trench 427 may be etched or otherwise formed in the gate oxide 450 in the primary trench 434, as shown in 338 and seen in FIG. 5F. The SBD trench 427 may be etched or otherwise formed in the gate oxide 450 at a side (as shown in the figures, the right side) of the primary trench 434 that is opposite the doped source region 430. The SBD trench 427 may be etched so as to remove all of the gate oxide 450 at one side and/or the bottom of the primary trench 434. A Schottky material 452, which may become the Schottky material 52, 152, 252 may be deposited or otherwise provided in the SBD trench 427 such that the Schottky material 452 is at least in part in physical contact with the semiconductor material 422, as shown in 340 and seen in FIG. 5G. An SBD contact 454, which may become the SBD contact 54, 154, 254 may be provided in physical contact with the Schottky material 452, as shown in 342 and seen in FIG. 5H. The Schottky material 452 may include aluminum, titanium, molybdenum, platinum, chromium, and tungsten and combinations thereof.

In one example, seen in FIGS. 1 and 5H, the Schottky material 452 may line the SBD trench 427 and the SBD contact 454 may extend at least in part into the trench 427 at least in part surrounded by the Schottky material 452. In another example, seen in FIG. 2, the Schottky material 452 may fill the SBD trench 427 and the SBD contact 454 may be provided on top of the Schottky material 452. In another example, seen in FIG. 3, the Schottky material 452 may extend along one side of the SBD trench 427 adjacent to and in physical contact with the semiconductor material 422, and the SBD contact 454 may extend along the other side of the SBD trench 427 adjacent to the gate oxide 450. In all examples, the Schottky material 452 may at least in part physically contact the semiconductor material 422 at some point. As seen in the figures, the FET gate 36, 136, 236 and the SBD 26,126, 226 may be separated from one another in the primary trench 434 by an intermediate portion of the gate oxide 450 that remains after the gate trench 437 and the SBD trench 427 have been etched.

The method may further include providing a first electrical terminal 456 that electrically connects the doped source region 430, the doped well region 436 via the doped body region 446, and the SBD contact 426; a second electrical terminal 458 on the substrate (drain) 432; and a third electrical terminal 60 on the doped gate material 434, as shown in 344 and seen in FIG. 5H, for applying appropriate voltages during operation.

Additional operations may be performed as desired.

Although described herein with regard or in relation to one or more particular kinds of electronic devices (e.g., junction field-effect transistors, metal oxide semiconductor field-effect transistors), the technology may be more broadly applicable to one or more other kinds of electronic devices as well. One with ordinary skill in the art will recognize that the technology described herein may, when applicable, be implemented in enhancement mode or depletion mode. Further, the technology described herein may, when applicable, be implemented as an N-channel or P-channel device, wherein, in general, regions that are N-doped or P-doped in N-channel implementations may be, respectively, P-doped or N-doped in P-channel implementations. Additionally, the various example materials identified herein may, in some aspects, be replaced or supplemented with substantially any other suitable material. For example, gate material may include polysilicon, a metal or alloy of metals, or other suitable material; gate oxide or dielectric may include silicon dioxide, aluminum oxide, hafnium dioxide, silicon nitride, or other suitable material; and semiconductor material may include silicon carbide, gallium nitride, zinc oxide, or other suitable material.

Additionally, in general, unless otherwise specified or unless one with ordinary skill in the art would understand otherwise, doping characterized as "++" (e.g., P++) will have a relatively higher concentration of dopants than "+" (e.g., P+) doping, "+" doping will have a relatively higher concentration than "-well" (e.g., P-well) doping, and "-well" doping will have a relatively higher concentration of doping than "-" (e.g., P-) doping. In general, doping concentrations (typically measured in parts-per-cubic-centimeter) for contact implants (e.g., sources, drains, body contacts) may be approximately between 5x10^18 and 1x10^22; doping concentrations for channel and threshold forming implants (e.g., P-wells) may be approximately between 5x10^15 and 5x10^17; doping concentrations for shielding implants may be approximately between 5x10^17 and 5x10^19; and doping concentrations for conductivity improvement implants (e.g., N- doping in the junction field-effect transistor neck region of a metal oxide semiconductor field-effect transistor) may be approximately between 1x10^17 and 1x10^19.

Relatedly, a structure or region may contain two or more different doping doses. In various examples, dopant concentrations within a given structure or region may vary within the example range described above for the corresponding region type. Dopant concentration may vary according to a gradient that gradually decreases as the depth of the implant increases. Further, one with ordinary skill in the art will recognize that some P-wells may contain a lower dose P-well portion and a higher dose unclamped inductive switching portion. Dopant concentration variation within a given structure or region may result from normal manufacturing variance, may be by design, or may otherwise arise without departing from the spirit of the present disclosure.

Additionally, although only one or a few instances of a device or apparatus may be described herein, it will be appreciated that some applications may involve many such devices or apparatuses, which may be different from, substantially similar to, or identical to the described device or apparatus, and which may be arranged (e.g., in an array) on a larger extension of the volume of semiconductor material. In that light, references to a right and/or left side of a volume of semiconductor material may be to the conceptual limit of a particular unit cell and not to an actual physical end of the material.

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure as contemplated by the inventors.

What is claimed is:

1. A semiconductor device comprising:
a volume of semiconductor material presenting oppositely spaced apart first and second ends, with a trench extending from the first end of the volume of semiconductor material;
an integrated metal-oxide semiconductor field-effect transistor (MOSFET) including:
a source located adjacent the first end of the volume of semiconductor material,
a drain spaced from the source such that a channel extends through the volume of semiconductor material between the source and the drain,
a gate-oxide located within the trench, and
a gate material at least in part surrounded by the gate oxide within the trench; and
an integrated Schottky barrier diode (SBD) that is located at least in part within the trench and contacts the volume of semiconductor material.

2. The semiconductor device of claim 1,
the drain being located at the second end of the volume of semiconductor material.

3. The semiconductor device of claim 1,
the SBD contacting the gate oxide within the trench.

4. The semiconductor device of claim 3,
the SBD including a Schottky metal and an SBD contact, each of which includes at least a portion thereof located within the trench.

5. The semiconductor device of claim 4,
the Schottky metal and the SDB contact being integrally formed.

6. The semiconductor device of claim 4,
the Schottky metal being interposed between the SBD contact and the gate oxide and between the SBD contact and the volume of semiconductor material.

7. The semiconductor device of claim 4,
the SBD contact being interposed between the Schottky metal and the gate oxide.

8. The semiconductor device of claim 4,
the trench having a trench bottom surface spaced from the first end of the volume of semiconductor material,
the Schottky metal extending continuously between the trench bottom surface and the first end of the volume of semiconductor material.

9. The semiconductor device of claim 8,
the SBD contact being spaced from the trench bottom surface.

10. The semiconductor device of claim 3,
the volume of semiconductor material presenting opposite laterally spaced first and second sides, and
the trench having a trench bottom surface and opposite first and second laterally spaced trench side surfaces, each of which extends between the first end of the volume of semiconductor material and the trench bottom surface.

11. The semiconductor device of claim 10,
the gate oxide lining the first trench side surface and at least a portion of the trench bottom surface,
the source being located between the first side of the volume of semiconductor material and the first trench side surface,
the SBD being located adjacent the second trench side surface.

12. The semiconductor device of claim 11,
the MOSFET including a first doped well contacting the source and the gate oxide to define a portion of the channel extending between the source and drain,
the MOSFET including a second doped well located below the trench bottom surface.

13. The semiconductor device of claim 12,
the second doped well and the first trench side surface being equally spaced from the first side of the volume of semiconductor material,
the second doped well being spaced closer to the second side of the volume of semiconductor material than the second trench side surface.

14. The semiconductor device of claim 12,
the first doped well including a channel-defining first portion at the first trench side surface, with the channel-defining first portion being spaced from the trench bottom surface so as to expose the gate oxide along a portion of the first trench side surface,
the first doped well including a second portion spaced from the first trench side surface,
the second portion projecting further toward the second end of the volume of semiconductor material than the trench bottom surface and cooperating with the second doped well to define a JFET region therebetween.

15. The semiconductor device of claim 12,
the SBD contacting the second doped well.

16. The semiconductor device of claim 11,
the MOSFET including a well contacting the source and the gate oxide, which is the only source-well-oxide interface of the MOSFET so as to define a single channel extending between the source and drain.

17. The semiconductor device of claim 3,
the trench having opposite first and second spaced apart trench side surfaces, each of which extends from the first end of the volume of semiconductor material,
the SBD being located along at least a portion of the second trench side surface,
the gate oxide including a first side oxide portion lining the first trench side surface and a second side oxide portion located between the gate material and the SBD,
the second side oxide portion being thicker, in a dimension measured between the first and second trench side surfaces, than the first side oxide portion.

18. The semiconductor device of claim 17,
the SBD including a Schottky metal that has at least a portion thereof lining the second trench side surface,
the SBD including an SBD contact located between the second side oxide portion and the at least a portion of the Schottky metal.

19. The semiconductor device of claim 1,
the trench having a trench bottom surface and opposite first and second laterally spaced trench side surfaces, each of which extends between the first end of the volume of semiconductor material and the trench bottom surface,
the MOSFET including a first doped well contacting the source and the gate oxide to define a portion of the channel extending between the source and drain,
the MOSFET including a second doped well located below the trench bottom surface,
the SBD contacting the second doped well.

20. The semiconductor device of claim 1, comprising:
an electrical connection electrically connecting the MOSFET and the SBD.
